(19) United States
(12) Patent Application Publication
(10) Pub. No.: US 2026/0026188 A1
(43) Pub. Date: Jan. 22, 2026

(54) DISPLAY DEVICE AND METHOD OF MANUFACTURING SAME

(71) Applicant: LG Display Co., Ltd., Seoul (KR)

(72) Inventors: Han Seung YANG, Paju-si (KR); Bum Jong PARK, Paju-si (KR); Han Wool PARK, Paju-si (KR)

(73) Assignee: LG Display Co., Ltd., Seoul (KR)

(21) Appl. No.: 19/237,965

(22) Filed: Jun. 13, 2025

(30) Foreign Application Priority Data
Jul. 19, 2024 (KR) 10-2024-0095929

(51) Int. Cl. H10K 50/13; H10K 50/17; H10K 59/12; H10K 59/122; H10K 102/00

(52) U.S. Cl. CPC H10K 50/13; H10K 50/17; H10K 59/1201; H10K 59/122; H10K 2102/351

(57) ABSTRACT

Provided is a display device including a first electrode layer, a bank layer exposing the first electrode layer, an element layer positioned on the first electrode layer and the bank layer and configured to emit at least three colors, and a second electrode layer positioned on the element layer. The element layer may include a first hole injection layer positioned on the first electrode layer, and a second hole injection layer positioned on the bank layer and having a different thickness from the first hole injection layer.

This application claims the benefit of Korean Patent Application No. 10-2024-0095929, filed on Jul. 19, 2024, which is hereby incorporated by reference as if fully set forth herein.

### BACKGROUND

### Field of the Disclosure

The present disclosure relates to a display device and a method of manufacturing the same.

### Discussion of the Related Art

As information technology develops, the market for display devices serving as connecting media between users and information, is growing. Accordingly, the use of display devices such as light emitting display (LED) devices, quantum dot display (QDD) devices, and liquid crystal display (LCD) devices is increasing.

The display devices described above include a display panel including subpixels, a driver that outputs a driving signal to drive the display panel, and a power supply that generates power to be supplied to the display panel or the driver.

The display devices described above can display images by allowing selected subpixels to transmit light or directly emit light when driving signals, such as a gate signal and a data signal, are supplied to the subpixels formed on the display panel.

### SUMMARY

Accordingly, the present disclosure is directed to a display device and a method of manufacturing the same that substantially obviate one or more problems due to limitations and disadvantages of the related art.

An object of the present disclosure is to reduce or improve the phenomenon of over-emission at the edge (end) of a white light-emitting element and prevent or suppress color mixing defects caused by emission of adjacent subpixels.

Another object of the present disclosure is to improve display quality when manufacturing a display panel based on a white light-emitting element including element layers emitting at least three colors.

Additional advantages, objects, and features of the present disclosure will be set forth in part in the description which follows and in part will become apparent to those having ordinary skill in the art upon examination of the following or may be learned from practice of the present disclosure. The objectives and other advantages of the present disclosure may be realized and attained by the structure particularly pointed out in the written description and claims hereof as well as the appended drawings.

To achieve these objects and other advantages and in accordance with the purpose of the present disclosure, as embodied and broadly described herein, a display device includes a first electrode layer, a bank layer exposing the first electrode layer, an element layer positioned on the first electrode layer and the bank layer and configured to emit at least three colors, and a second electrode layer positioned on the element layer, wherein the element layer includes a first hole injection layer positioned on the first electrode layer and a second hole injection layer positioned on the bank layer and having a different thickness from the first hole injection layer.

In another aspect of the present disclosure, a display device includes a first electrode layer, a bank layer exposing the first electrode layer, an element layer positioned on the first electrode layer and the bank layer and configured to emit at least three colors, and a second electrode layer positioned on the element layer, wherein the element layer includes a first hole injection layer positioned on the first electrode layer and a second hole injection layer positioned on the bank layer and having a different resistance value from the first hole injection layer.

In the element layer, the second hole injection layer positioned on the bank layer may be thicker than the first hole injection layer positioned on the first electrode layer.

In the element layer, the resistance value of the second hole injection layer positioned on the bank layer may be lower than a resistance value of the first hole injection layer positioned on the first electrode layer.

The element layer may be configured to emit white light based on layers laminated in the order of a red element layer, a blue element layer, and a green element layer.

The element layer may be configured to emit white light based on layers laminated in the order of a red element layer, a first blue element layer, a green element layer, and a second blue element layer.

The bank layer may include a recessed or protruding structure.

In yet another aspect of the present disclosure, a method of manufacturing a display device includes forming a first electrode layer, forming a bank layer exposing the first electrode layer, forming an element layer configured to emit at least three colors on the first electrode layer and the bank layer, and forming a second electrode layer on the element layer, wherein the forming of the element layer includes forming a first hole injection layer on the first electrode layer and the bank layer using a first source, and forming a second hole injection layer on the bank layer using a second source.

The forming of the second hole injection layer may include using a mask exposing only the bank layer and blocking the remaining area.

The first source and the second source may be identical or different.

It is to be understood that both the foregoing general description and the following detailed description of the present disclosure are by way of example and explanatory and are intended to provide further explanation of the present disclosure as claimed.

### BRIEF DESCRIPTION OF THE DRAWINGS

The accompanying drawings, which are included to provide a further understanding of the present disclosure and are incorporated in and constitute a part of this application, illustrate example embodiment(s) of the present disclosure and together with the description serve to explain various principles of the present disclosure. In the drawings:

FIG. 1 is a block diagram schematically illustrating an example light-emitting display device;

FIG. 2 and FIG. 3 are diagrams illustrating an example configuration of a gate-in-panel type gate driver;

FIG. 4 is a circuit configuration diagram of a subpixel according to a first example;

FIG. 5 is a circuit configuration diagram of a subpixel according to a second example;

FIG. 6 is a diagram illustrating an example white light-emitting element according to the first example;

FIG. 7 is a diagram illustrating an example white light-emitting element according to the second example;

FIG. 8 is a plan view of a subpixel according to an example embodiment of the present disclosure;

FIG. 9 is a cross-sectional view along line X1-X2 in FIG. 8.

FIG. 10 and FIG. 11 are diagrams illustrating a subpixel according to an example embodiment;

FIG. 12 and FIG. 13 are diagrams illustrating a subpixel according to a comparative example;

FIG. 14 shows simulation results of an over-emission ratio according to the resistance of a hole injection layer;

FIG. 15 shows simulation results of maximum over-emission according to the resistance ratio of a charge generation layer and the hole injection layer;

FIG. 16 and FIG. 17 are diagrams for describing a first method of implementing a structure of a hole injection layer according to an example embodiment of the present disclosure;

FIG. 18 and FIG. 19 are diagrams for describing a second method of implementing the structure of the hole injection layer according to an example embodiment of the present disclosure; and

FIG. 20 and FIG. 21 are diagrams for describing a third method of implementing the structure of the hole injection layer according to an example embodiment of the present disclosure.

### DETAILED DESCRIPTION

Reference will now be made in detail to various embodiments of the present disclosure, examples of which are illustrated in the accompanying drawings.

A display device according to the present disclosure may be implemented as a television, a video player, a personal computer (PC), a home theater, an automobile electrical device, a smartphone, a personal immersive device (VR, MR, or XR), or the like, but the present disclosure is not limited thereto. The display device according to the present disclosure may be implemented as a light emitting display (LED) device, a quantum dot display (QDD) device, a liquid crystal display (LCD) device, or the like. However, for convenience of description, a light emitting display device that directly emits light based on inorganic light-emitting diodes or organic light-emitting diodes is used as an example of the display device.

In addition, a transistor which will be described below may be implemented as an n-type transistor, a p-type transistor, or a form including both n-type and p-type transistors. The transistor is a three-electrode element including a gate, a source, and a drain. The source is an electrode that supplies carriers to the transistor. In the transistor, carriers start to flow from the source. The drain is an electrode through which carriers leave the transistor. In other words, carriers flow from the source to the drain in the transistor.

In the case of a p-type transistor, holes serve as carriers, and thus a source voltage is higher than a drain voltage such that the holes can flow from the source to the drain. Since the holes flow from the source to the drain in the p-type transistor, the current flows from the source to the drain. In contrast, in the case of an n-type transistor, electrons serve as carriers, and thus the source voltage is lower than the drain voltage such that the electrons can flow from the source to the drain. Since the electrons flow from the source to the drain in the n-type transistor, the current flows from the drain to the source. However, the source and drain of a transistor can be changed depending on the applied voltage. To reflect this, in the following description, one of the source and drain is described as a first electrode, and the other of the source and drain is described as a second electrode.

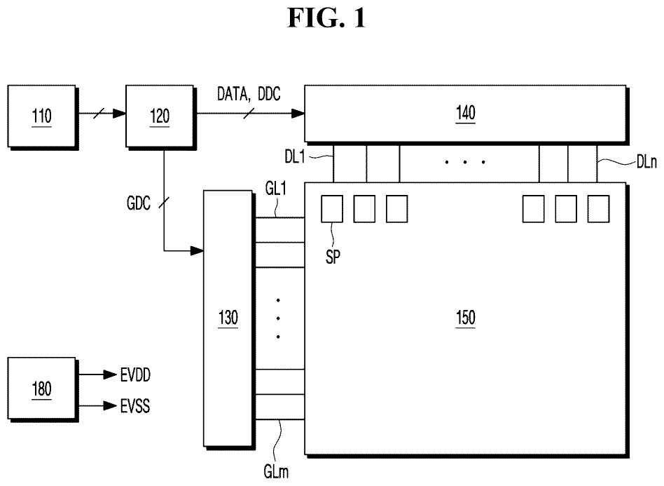

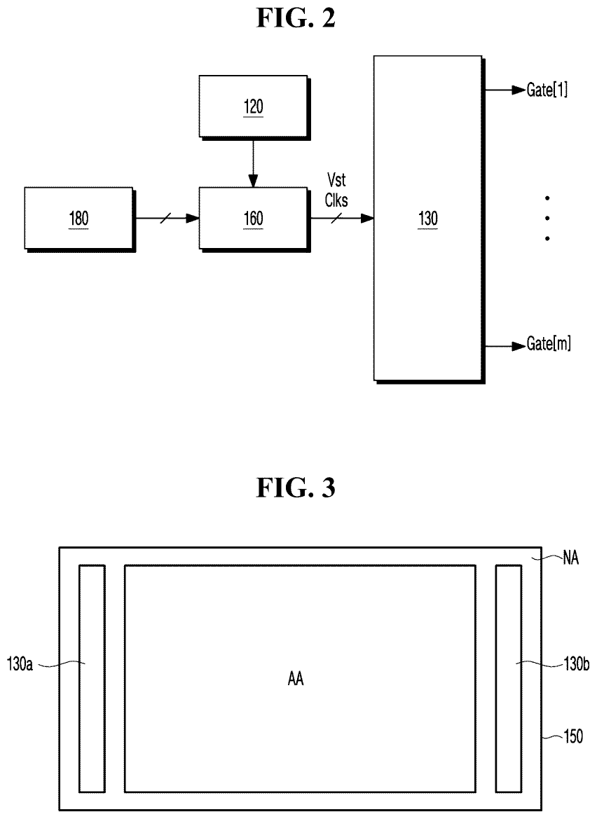

FIG. 1 is a block diagram schematically showing an example light-emitting display device, and FIG. 2 and FIG. 3 are diagrams illustrating an example configuration of a gate-in-panel type gate driver.

As illustrated in FIG. 1 to FIG. 3, the light-emitting display device may include a timing controller 120, a gate driver 130, a data driver 140, a display panel 150, and a power supply 180.

An image provider (set or host system) 110 may output various driving signals in addition to an image data signal supplied from the outside or an image data signal stored in an internal memory. The image provider 110 may supply a data signal and various driving signals to the timing controller 120.

The timing controller 120 may output a gate timing control signal GDC for controlling the operation timing of the gate driver 130, a data timing control signal DDC for controlling the operation timing of the data driver 140, and various synchronization signals (a vertical synchronization signal Vsync and a horizontal synchronization signal Hsync), etc. The timing controller 120 may supply a data signal DATA supplied from the image provider 110 along with the data timing control signal DDC to the data driver 140. The timing controller 120 may take the form of an integrated circuit (IC) and be mounted on a printed circuit board, but the present disclosure is not limited thereto.

The gate driver 130 may output a gate signal (or a gate voltage) in response to the gate timing control signal GDC supplied from the timing controller 120. The gate driver 130 may supply gate signals to subpixels included in the display panel 150 through gate lines GL1 to GLm. The gate driver 130 may be formed as an IC or directly formed on the display panel 150 in a gate-in-panel structure, but the present disclosure is not limited thereto. However, for convenience of description, a gate-in-panel type gate driver will be described below as an example, as shown in FIG. 2 and FIG. 3.

The gate-in-panel type gate driver 130 may include shift registers 130a and 130b formed in a gate-in-panel type on one side and the other side of a non-active area NA of the display panel 150. The shift registers 130a and 130b may be formed in the form of a thin film in the gate-in-panel type in the non-active area NA of the display panel 150. The gate-in-panel type gate driver 130 may output gate signals Gate[1] to Gate[m] for turning on or off transistors formed in the active area AA of the display panel 150.

The gate-in-panel type gate driver 130 may operate based on signals and voltages output from the timing controller 120, the power supply 180, and a level shifter 160. The level shifter 160 may generate gate control signals required for operation of the gate-in-panel type gate driver 130, 130a, and 130b on the basis of signals and voltages output from the timing controller 120 and the power supply 180.

The data driver 140 may sample and latch a data signal DATA in response to the data timing control signal DDC supplied from the timing controller 120 and convert a digital data signal into an analog data voltage on the basis of a gamma reference voltage and output the analog data voltage. The data driver 140 may supply data voltages to subpixels included in the display panel 150 through data lines DL1 to DLn. The data driver 140 may be formed as an IC and mounted on the display panel 150 or on a printed circuit board, but the present disclosure is not limited thereto.

The power supply 180 may generate a high-level voltage and a low-level voltage based on an external input voltage supplied from the outside, and output the same through a high-level voltage line EVDD and a low-level voltage line EVSS. The power supply 180 may generate and output not only the high-level voltage and the low-level voltage, but also voltages required for operation of the gate driver 130 or voltages required for operation of the data driver 140.

The display panel 150 may be manufactured based on a rigid or flexible substrate such as glass, silicon, or polyimide. The display panel 150 may include a plurality of subpixels SP for displaying an image. The subpixels SP can directly emit light to an upper substrate, a lower substrate, or the upper and lower substrates of the display panel 150. The subpixels SP may emit one of colors, such as red, green, blue, and white. The display panel 150 may display an image based on pixels composed of red subpixels, green subpixels, and blue subpixels, or pixels composed of red subpixels, green subpixels, blue subpixels, and white subpixels.

In the above description, the timing controller 120, the gate driver 130, the data driver 140, etc. are described as separate components. However, depending on the implementation of the light-emitting display device, one or more of the timing controller 120, the gate driver 130, and the data driver 140 may be integrated into one IC.

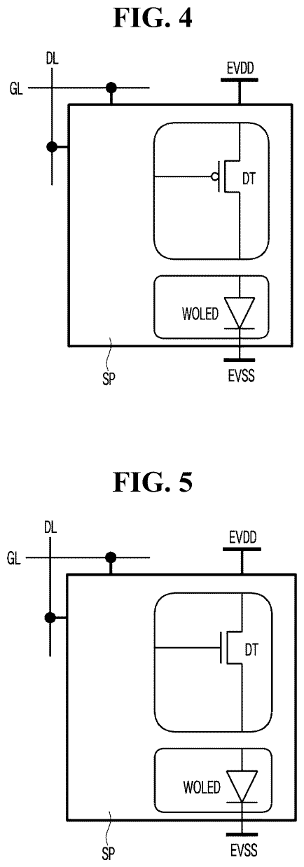

FIG. 4 is a circuit configuration diagram of a subpixel according to a first example, and FIG. 5 is a circuit configuration diagram of a subpixel according to a second example.

As illustrated in FIG. 4, the subpixel SP according to the first example may include a driving transistor DT configured as a p-type transistor and a white light-emitting element WOLED that emits white light. The p-type driving transistor DT may operate in response to a gate voltage applied as a low voltage.

As illustrated in FIG. 5, the subpixel SP according to the second example may include a driving transistor DT configured as an n-type transistor and a white light-emitting element WOLED that emits white light. The n-type driving transistor DT may operate in response to a gate voltage applied as a high voltage.

According to the present disclosure, the subpixel SP may include a capacitor that stores a data voltage, a switching transistor for transmitting the data voltage, a transistor for compensating for deterioration, etc. in addition to the driving transistor DT that generates a driving current and the white light-emitting element WOLED that emits light. FIG. 4 and FIG. 5 are provided to show that the driving transistor DT may be configured as a p-type or n-type transistor. Therefore, the configuration of the subpixel SP that may be included in the present disclosure is not limited to FIG. 4 and FIG. 5.

Hereinafter, a configuration of a white light-emitting element WOLED according to an embodiment of the present disclosure will be described.

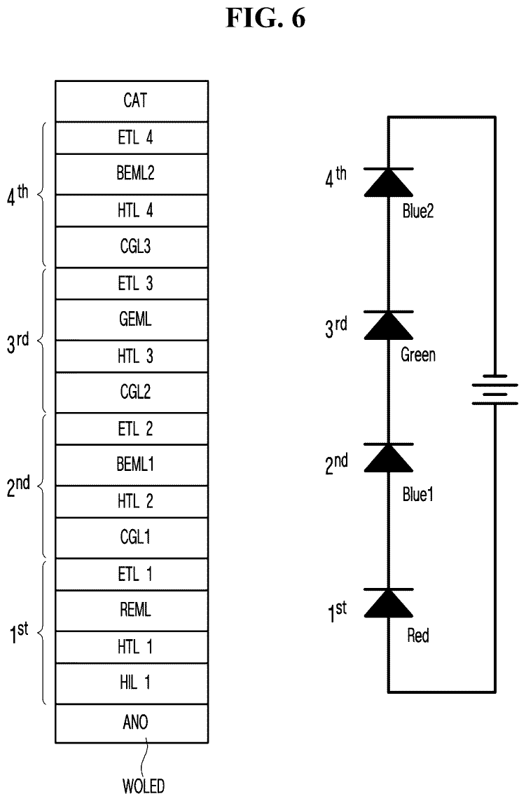

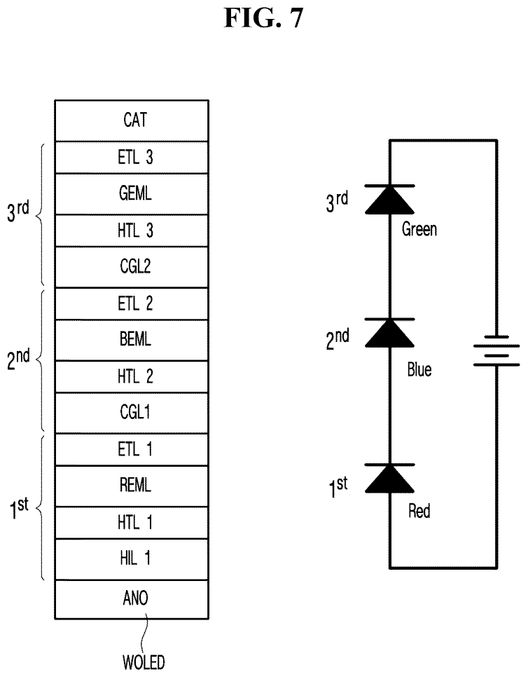

FIG. 6 is a diagram illustrating an example white light-emitting element according to the first example, and FIG. 7 is a diagram illustrating an example white light-emitting element according to the second example.

As illustrated in FIG. 6, the white light-emitting element WOLED according to the first example may have four element layers positioned between an anode layer ANO that is the lowest layer and a cathode layer CAT that is the uppermost layer. The four element layers may include a first element layer 1st, a second element layer 2nd, a third element layer 3rd, and a fourth element layer 4th. For example, the first element layer 1st may be a red element layer Red that emits red light, the second element layer 2nd may be a first blue element layer Blue1 that emits blue light, the third element layer 3rd may be a green element layer Green that emits green light, and the fourth element layer 4th may be a second blue element layer Blue2 that emits blue light. That is, the white light-emitting element WOLED according to the first example may emit white light based on the red element layer Red, the first blue element layer Blue1, the green element layer Green, and the second blue element layer Blue2.

According to the first example, the first element layer 1st may include a hole injection layer HIL1, a first hole transport layer HTL1, a red emission layer REML, and a first electron transport layer ETL1. The second element layer 2nd may include a first charge generation layer CGL1, a second hole transport layer HTL2, a first blue emission layer BEML1, and a second electron transport layer ETL2. The third element layer 3rd may include a second charge generation layer CGL2, a third hole transport layer HTL3, a green emission layer GEML, and a third electron transport layer ETL3. The fourth element layer 4th may include a third charge generation layer CGL3, a fourth hole transport layer HTL4, a second blue emission layer BEML2, and a fourth electron transport layer ETL4.

As illustrated in FIG. 7, the white light-emitting element WOLED according to the second example may have three element layers positioned between an anode layer ANO (or first electrode layer) that is the lowest layer and a cathode layer CAT (or second electrode layer) that is the uppermost layer.

The three element layers may include a first element layer 1st, a second element layer 2nd, and a third element layer 3rd. For example, the first element layer 1st may be a red element layer Red that emits red light, the second element layer 2nd may be a blue element layer Blue that emits blue light, and the third element layer 3rd may be a green element layer Green that emits green light. That is, the white light-emitting element WOLED according to the second example may emit white light based on the red element layer Red, the blue element layer Blue, and the green element layer Green.

According to the second example, the first element layer 1st may include a hole injection layer HIL1, a first hole transport layer HTL1, a red emission layer REML, and a first electron transport layer ETL1. The second element layer 2nd may include a first charge generation layer CGL1, a second hole transport layer HTL2, a blue emission layer BEML, and a second electron transport layer ETL2. The third element layer 3rd may include a second charge generation layer CGL2, a third hole transport layer HTL3, a green emission layer GEML, and a third electron transport layer ETL3.

As can be seen in the first and second examples, the white light-emitting element WOLED may include at least three element layers 1st to 3rd or 1st to 4th to express white, and the element layers 1st to 3rd or 1st to 4th may have a structure in which they are connected in series through charge generation layers CGL1 and CGL2 or CGL1 to CGL3.

In the first and second examples, each emission layer included in the white light-emitting element WOLED may include a plurality of host materials or a single host material, and the functional layers other than the emission layers may be formed of materials selected from the following materials.

The hole injection layer HIL1 may be formed of a material selected from HAT-CN (dipyrazino[2,3-f: 2′,3′-h]quinoxaline-2,3,6,7,10.11-hexacarbonitrile), CuPc (phthalocyanine), F4-TCNQ (2,3,5,6-tetrafluoro-7,7,8,8-tetracyano-quinodimethane), and NPD (N,N′-bis(naphthalene-1-yl)-N,N′-bis(phenyl)-2,2′-dimethylbenzidine), but the present disclosure is not limited thereto.

The first hole transport layer HTL1, the second hole transport layer HTL2, and the third hole transport layer HTL3 may be formed of a material selected from NPD (N,N′-bis(naphthalene-1-yl)-N,N′-bis(phenyl)-2,2′-dimethylbenzidine), TPD (N,N′-bis-(3-methylphenyl)-N,N′-bis(phenyl)-benzidine), s-TAD (2,2′,7,7′-tetrakis(N,N-dimethylamino)-9,9-spirofluorene), and MTDATA (4,4′,4″-Tris(N-3-methylphenyl-N-phenyl-amino)-triphenylamine), but the present disclosure is not limited thereto.

The first electron transport layer ETL1, the second electron transport layer ETL2, and the third electron transport layer ETL3 may be formed of a material selected from Liq (8-hydroxyquinolinolato-lithium), PBD (2-(4-biphenyl)-5-(4-tert-butylphenyl)-1,3,4-oxadiazole), TAZ (3-(4-biphenyl) 4-phenyl-5-tert-butylphenyl-1,2,4-triazole), BCP (2,9-Dimethyl-4,7-diphenyl-1,10-phenanthroline), and BAlq (bis(2-methyl-8-quinolinolate)-4-(phenylphenolato)aluminium) but the present disclosure is not limited thereto.

The first charge generation layer CGL1 and the second charge generation layer CGL2 may include an N-type charge generation layer and a P-type charge generation layer. The N-type charge generation layer may include an N-type dopant material and an N-type host material. The N-type dopant material may be, for example, any one of an alkali metal such as lithium (Li), sodium (Na), potassium (K), or cesium (Cs), and an alkaline earth metal such as magnesium (Mg), strontium (Sr), barium (Ba), or radium (Ra).

The N-type host material is a material capable of transferring electrons, for example, Alq3 (tris(8-hydroxyquinolino)aluminum), Liq (8-hydroxyquinolinolato-lithium), PBD (2-(4-biphenylyl)-5-(4-tert-butylphenyl)-1,3,4oxadiazole), TAZ (3-(4-biphenyl) 4-phenyl-5-tert-butylphenyl-1,2,4-triazole), spiro-PBD, and BAlq (bis(2-methyl-8-quinolinolate)-4-(phenylphenolato)aluminium), SAlq, TPBi (2,2′,2-(1,3,5-benzinetriyl)-tris(1-phenyl-1-H-benzimidazole), oxadiazole, triazole, phenanthroline, benzoxazole or benzthiazole, but is not limited thereto.

The P-type charge generation layer may include a P-type dopant material and a P-type host material. The P-type dopant material may be, for example, an organic material such as a metal oxide, tetrafluoro-tetracyanoquinodimethane (F4-TCNQ), HAT-CN (hexaazatriphenylene-hexacarbonitrile), or hexaazatriphenylene, or a metal material such as V₂O₅, MoOx, or WO3.

The P-type host material may be, for example, any one of NPD (N,N-dinaphthyl-N,N′-diphenyl benzidine), α-NPD (N,N′-bis(naphthalene-1-yl)-N,N′-bis(phenyl)-2,2′-dimethylbenzidine), TPD (N,N′-bis-(3-methylphenyl)-N,N′-bis-(phenyl)-benzidine), and MTDATA (4,4′,4-Tris(N-3-methylphenyl-N-phenyl-amino)-triphenylamine), but is not limited thereto.

Hereinafter, a subpixel according to an embodiment of the present disclosure will be described based on the white light-emitting element WOLED of the first example.

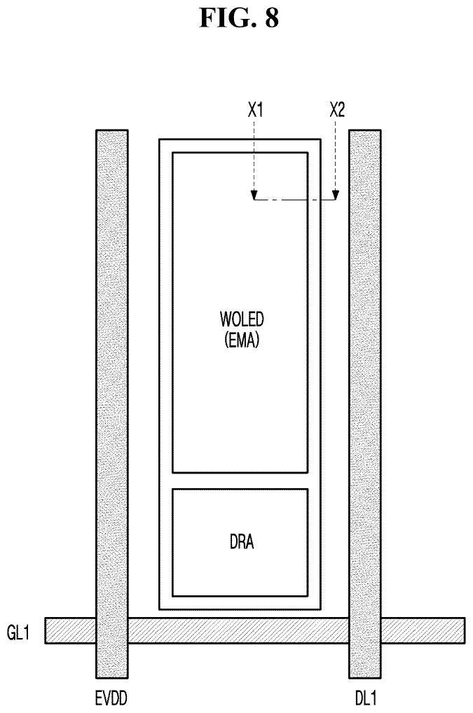

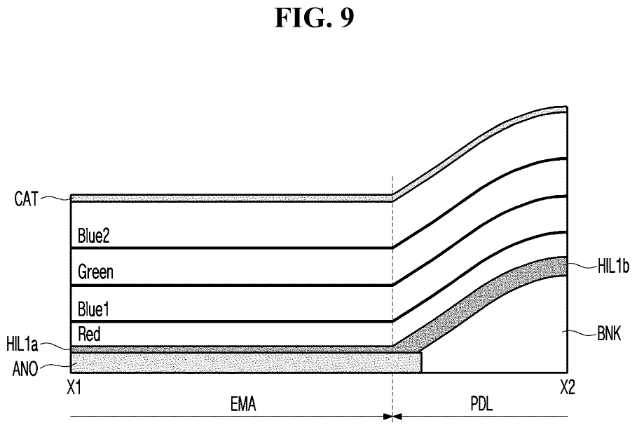

FIG. 8 is a plan view of a subpixel according to an example embodiment of the present disclosure, and FIG. 9 is a cross-sectional view along line X1-X2 in FIG. 8.

As illustrated in FIG. 8, the subpixel according to an embodiment may be defined by a high-level voltage line EVDD disposed in a first direction, a first gate line GL1 disposed in a second direction, and a first data line DL1 disposed in the first direction and spaced apart from the high-level voltage line EVDD. The subpixel may include an emission area EMA (or aperture area) including a white light-emitting element, and an element area DRA including a driving transistor, etc. However, the arrangement structure illustrated in FIG. 8 is merely an example and the present disclosure is not limited thereto.

As illustrated in FIG. 9, the emission area (EMA) that emits light may have a flat surface, and a pixel definition area PDL that defines a pixel (or defines the emission area/aperture area) may have an inclined surface. An insulating layer (or planarization layer) covering the driving transistor, etc. may be located below the emission area EMA and the pixel definition area PDL, but is omitted in the drawing.

An anode layer ANO, a red element layer Red, a first blue element layer Blue1, a green element layer Green, a second blue element layer Blue2, and a cathode layer CAT may be located in the emission area EMA. The anode layer ANO may be located on an insulating layer and connected to a source or drain electrode of a driving transistor located below the insulating layer.

A bank layer BNK, the red element layer Red, the first blue element layer Blue1, the green element layer Green, the second blue element layer Blue2, and the cathode layer CAT may be located in the pixel definition area PDL. The bank layer BNK may be located on the insulating layer and patterned to expose a portion of the anode layer ANO.

According to an embodiment, hole injection layers HIL1a and HIL1b in contact with the anode layer ANO and the bank layer BNK may be formed to have different resistance values. For example, the resistance value of the hole injection layer HIL1b located in the pixel definition area PDL (or on the bank layer) may be lower than the resistance value of the hole injection layer HIL1a located on the emission area EMA (or on the anode layer). That is, the embodiment can reduce the lateral resistance component of the hole injection layer HIL1b located in the pixel definition area PDL (or on the bank layer).

To this end, the hole injection layers HIL1a and HIL1b in contact with the anode layer ANO and the bank layer BNK may be formed to have different thicknesses. For example, the hole injection layer HIL1b located in the pixel definition area PDL may be thicker than the hole injection layer HIL1a located in the emission area EMA.

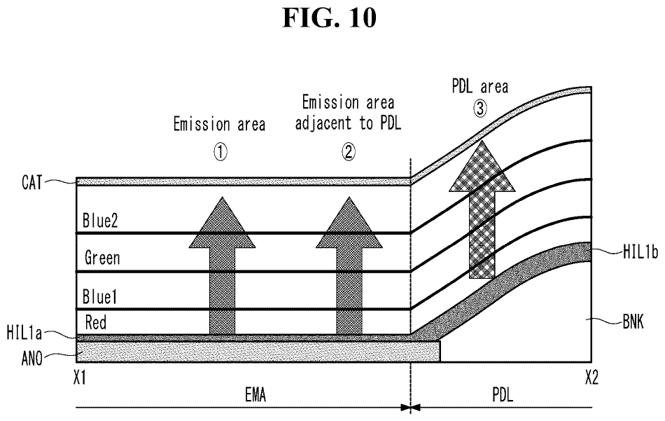

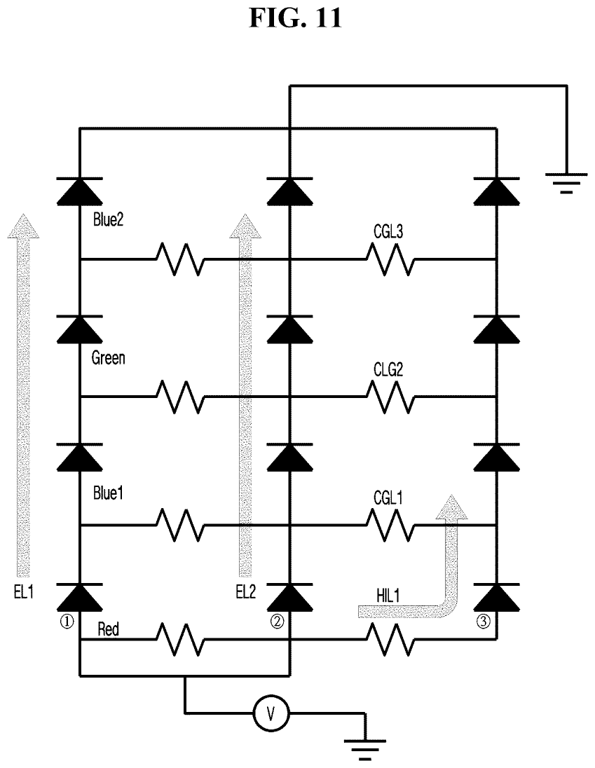

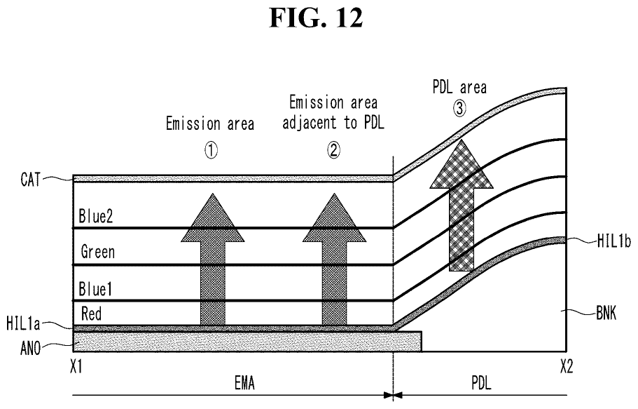

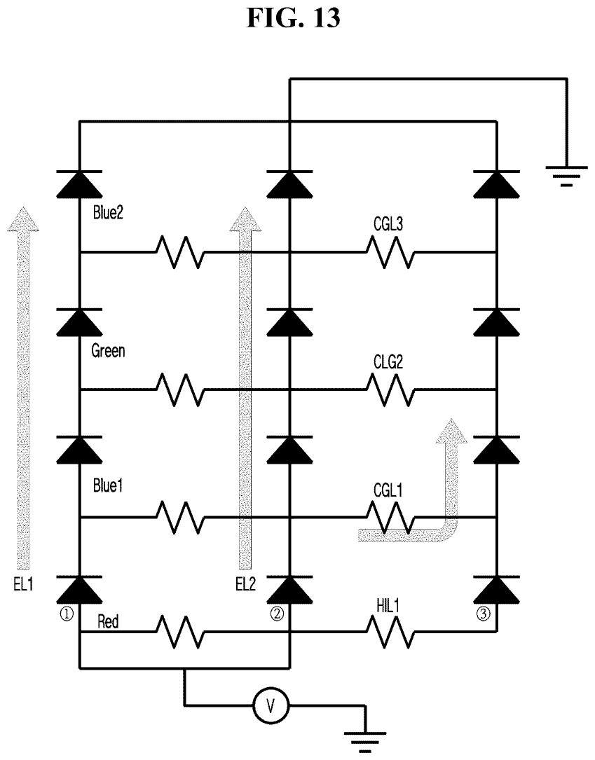

FIG. 10 and FIG. 11 are diagrams illustrating a subpixel according to an example embodiment, and FIG. 12 and FIG. 13 are diagrams illustrating a subpixel according to a comparative example.

As illustrated in FIG. 10 and FIG. 11, the subpixel according to the example embodiment may be formed such that the hole injection layer HIL1b located in the pixel definition area PDL is thicker than the hole injection layer HIL1a located in the emission area EMA. Accordingly, the resistance value of the hole injection layer HIL1b located in the pixel definition area PDL may be lower than the resistance value of the hole injection layer HIL1a located in the emission area EMA.

Accordingly, when a voltage V is applied to the anode layer ANO and the cathode layer CAT, the flow of current (or lateral leakage Current) in the pixel definition area PDL may occur through the hole injection layer HIL1b.

As illustrated in FIG. 12 and FIG. 13, the subpixel according to the comparative example may be formed such that the hole injection layer HIL1a located in the emission area EMA and the hole injection layer HIL1b located in the pixel definition area PDL have the same thickness. Accordingly, the resistance value of the hole injection layer HIL1a located in the emission area EMA may be the same as the resistance value of the hole injection layer HIL1b located in the pixel definition area PDL.

Accordingly, when a voltage V is applied to the anode layer ANO and the cathode layer CAT, the flow of current (or lateral leakage current) in the pixel definition area PDL may occur through the first charge generation layer CGL1.

As described above, the white light-emitting elements according to the embodiment and the comparative example may include at least three element layers 1st to 3rd or 1st to 4th to express white, and the element layers 1st to 3rd or 1st to 4th may have a structure in which they are connected in series through charge generation layers CGL1 and CGL2 or CGL1 to CGL3. However, according to experiments, it was found that the white light-emitting element may cause an over-emission phenomenon in the periphery \textcircled{2} of the emission area EMA compared to the center \textcircled{1} thereof when the white light-emitting element is driven at low luminance. For reference, the pixel definition area PDL is an area where no light emission occurs.

In the subpixel of the embodiment, since the resistance value of the hole injection layer HIL1b on the other side is lower than the resistance value of the hole injection layer HIL1a on one side, current can be induced to the hole injection layer HIL1b on the other side rather than the first charge generation layer CGL1 that causes over-emission. As a result, the subpixel of the embodiment can reduce or improve the over-emission phenomenon that may occur in the periphery \textcircled{2} of the emission area EMA.

On the other hand, in the subpixel of the comparative example, since the resistance value of the hole injection layer HIL1b on the other side is the same as the resistance value of the hole injection layer HIL1a on one side, current can flow to the first charge generation layer CGL1 that causes over-emission rather than the hole injection layer HIL1b. As a result, the subpixel of the comparative example may exhibit an over-emission phenomenon in the periphery \textcircled{2} of the emission area EMA, and color mixing defects may occur due to emission of adjacent sub-pixels.

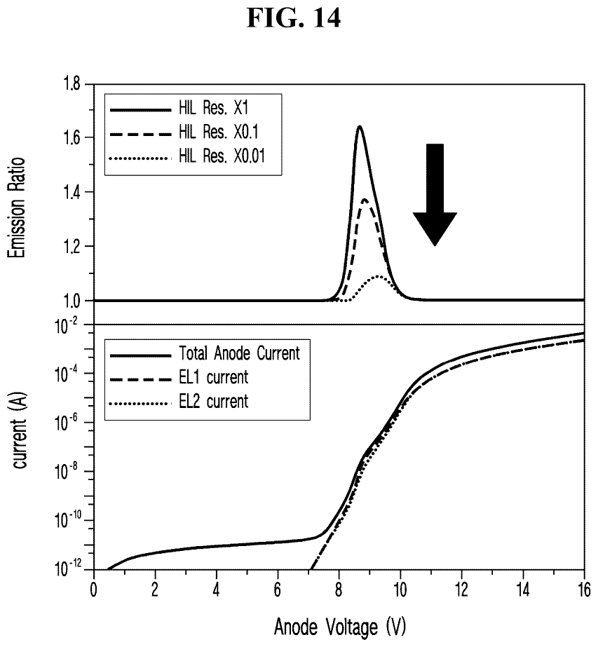

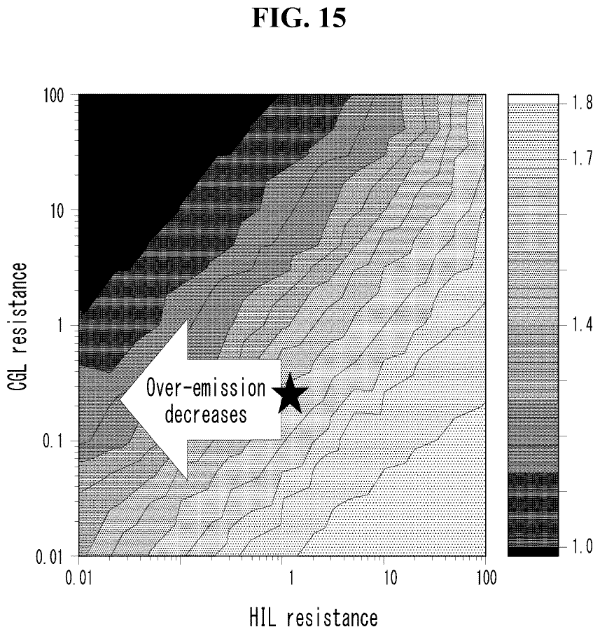

FIG. 14 shows simulation results of an over-emission ratio according to the resistance of a hole injection layer, and FIG. 15 shows simulation results of maximum over-emission according to the resistance ratio of a charge generation layer and the hole injection layer.

As shown in FIG. 14, it can be ascertained that the lower the resistance of the hole injection layer (HIL Res. X 1, HIL Res. X 0.1, HIL Res. X 0.01), the lower the over-emission ratio (Emission Ratio). This can be seen by referring to the total anode current of the white light-emitting element, the current of a first light-emitting element (EL1 current), and the current of a second light-emitting element (EL2 current).

As shown in FIG. 15, it can be ascertained that over-emission can be reduced by appropriately adjusting the ratio of the resistance of the charge generation layer and the resistance of the hole injection layer.

As can be ascertained from the simulation results of FIG. 14 and FIG. 15, the problem of over-emission occurring in a specific area can be reduced or addressed by forming the hole injection layer in a structure according to the embodiment, and color mixing defects due to emission of adjacent sub-pixels can be prevented or suppressed.

Hereinafter, a method of implementing a structure of a hole injection layer according to an embodiment of the present disclosure will be described. Only the process of forming the hole injection layer will be described as an example below.

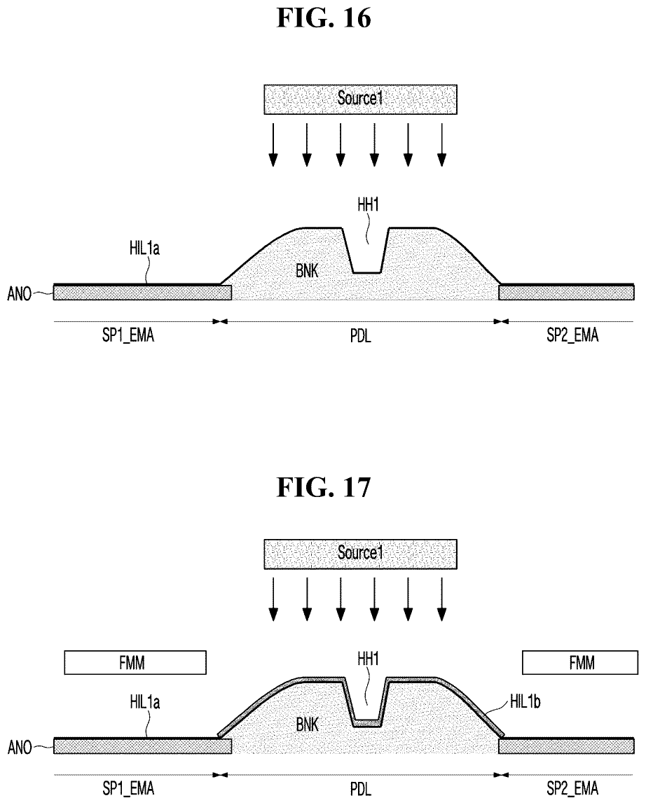

FIG. 16 and FIG. 17 are diagrams for describing a first method of implementing a structure of a hole injection layer according to an example embodiment of the present disclosure.

As illustrated in FIG. 16, a first source Source1 may be deposited on the entire area of a substrate including an emission area SP1_EMA of a first subpixel, an emission area SP2_EMA of a second subpixel, and a pixel definition area PDL located therebetween during a first period.

As illustrated in FIG. 17, the first source Source1 may be deposited on a portion of the substrate including only the pixel definition area PDL during a second period following the first period. Although the process time of the first period and the process time of the second period may be the same, the process for the first period and the process for the second period may be performed for different periods of time to control the thickness (or resistance value) of the hole injection layer HIL1a and HIL1b. For example, the process time of the second period may be longer than the process time of the first period.

According to the first method, the first source Source1 for forming the hole injection layer HIL1a and HIL1b may be formed on the substrate through a deposition process performed twice for the first period and the second period. During the second period, a mask such as a fine metal mask FMM that exposes only the bank layer BNK and blocks the remaining area may be used such that the first source Source1 is deposited only on the pixel definition area PDL, but the present disclosure is not limited thereto.

In addition, according to the first method, a first recess HH1 (or a first trench) may be formed in a non-sloping portion (or flat portion) of the bank layer BNK located in the pixel definition area PDL. The first recess HH1 may serve to prevent/suppress color mixing due to current leakage between the emission area SP1_EMA of the first subpixel and the emission area SP2_EMA of the second subpixel. To this end, the first recess HH1 may be formed such that the base surface and the sidewall surface form an obtuse angle (90° to) 180°, but the present disclosure is not limited thereto.

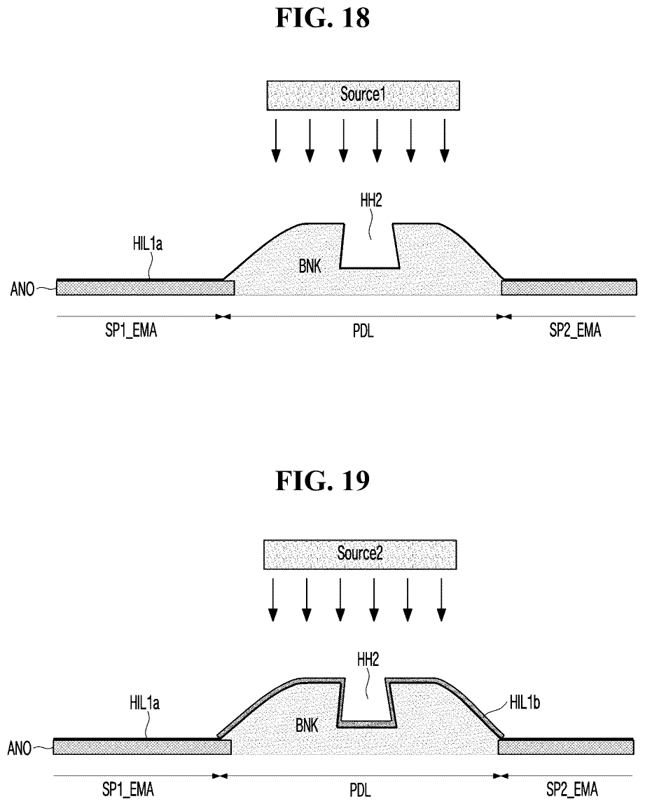

FIG. 18 and FIG. 19 are diagrams for describing a second method of implementing the structure of the hole injection layer according to an example embodiment of the present disclosure.

As illustrated in FIG. 18, the first source Source1 may be deposited on the entire area of the substrate including the emission area SP1_EMA of the first subpixel, the emission area SP2_EMA of the second subpixel, and the pixel definition area PDL located therebetween during the first period.

As illustrated in FIG. 19, a second source Source2 may be deposited on a portion of the substrate including only the pixel definition area PDL during the second period following the first period. The material of the first source Source1 may be the same as the material of the second source Source2, but different materials may be selected as the material of the first source Source1 and the material of the second source Source2 to control the resistance value (or thickness) of the hole injection layer HIL1a and HIL1b.

According to the second method, the first source Source1 for forming the hole injection layer HIL1a and HIL1b may be deposited on the entire area of the substrate during the first period, and the second source Source2 may be deposited on a portion of the substrate during the second period.

In addition, according to the second method, a second recess HH2 (or a second trench) may be formed in a non-sloping portion (or flat portion) of the bank layer BNK located in the pixel definition area PDL. The second recess HH2 may serve to prevent/suppress color mixing due to current leakage between the emission area SP1_EMA of the first subpixel and the emission area SP2_EMA of the second subpixel. To this end, the second recess HH2 may be formed such that the base surface and the sidewall surface form an acute angle (0° to 90°), but the present disclosure is not limited thereto.

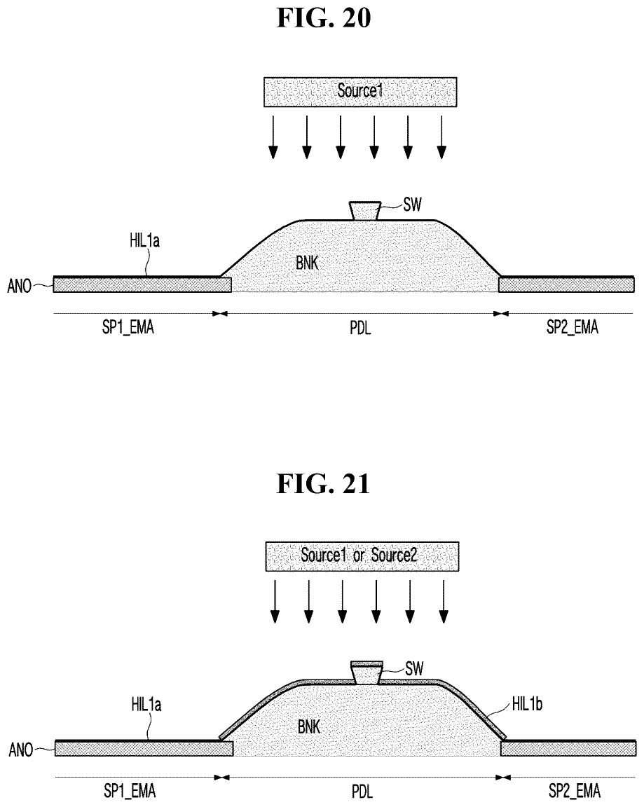

FIG. 20 and FIG. 21 are diagrams for describing a third method of implementing the structure of the hole injection layer according to an example embodiment of the present disclosure.

As illustrated in FIG. 20, the first source Source1 may be deposited on the entire area of the substrate including the emission area SP1_EMA of the first subpixel, the emission area SP2_EMA of the second subpixel, and the pixel definition area PDL located therebetween during the first period.

As illustrated in FIG. 21, the first source Source1 or the second source Source2 may be deposited on a portion of the substrate including only the pixel definition area PDL during the second period following the first period. The material of the first source Source1 may be the same as the material of the second source Source2, but different materials may be selected as the material of the first source Source1 and the material of the second source Source2 to control the resistance value (or thickness) of the hole injection layer HIL1a and HIL1b.

According to the third method, the first source Source1 for forming the hole injection layer HIL1a and HIL1b may be deposited on the entire area of the substrate during the first period, and the first source Source1 or the second source Source2 may be deposited on a portion of the substrate during the second period.

In addition, according to the third method, a partition wall SW (or a protrusion) may be formed on a non-sloping portion (or flat portion) of the bank layer BNK located in the pixel definition area PDL. The partition wall SW may serve to prevent/suppress color mixing due to current leakage between the emission area SP1_EMA of the first subpixel and the emission area SP2_EMA of the second subpixel. To this end, the partition wall SW may be formed to have a reverse taper shape, but the present disclosure is not limited thereto.

Meanwhile, in the first to third methods, the first recess HH1, the second recess HH2, and the partition wall SW are used as structures for preventing/suppressing color mixing due to current leakage between the emission area SP1_EMA of the first subpixel and the emission area SP2_EMA of the second subpixel, but the present disclosure is not limited thereto. That is, the first recess HH1 and the second recess HH2, which are recessed structures, and the partition wall SW, which is a protruding structure, should be interpreted as one example.

The present disclosure has the effect of reducing or improving the phenomenon of over-emission at the edge (end) of a white light-emitting element by varying the resistance value or thickness of the hole injection layer in certain areas. In addition, the present disclosure has the effect of preventing or suppressing color mixing defects caused by emission of adjacent subpixels by varying the resistance value or thickness of the hole injection layer in certain areas. Furthermore, the present disclosure has the effect of improving display quality when implementing a display panel based on a white light-emitting element including element layers emitting at least three colors.

It will be apparent to those skilled in the art that various modifications and variations can be made in the present disclosure without departing from the spirit or scope of the present disclosure. Thus, it is intended that the present disclosure cover the modifications and variations of the present disclosure provided they come within the scope of the appended claims and their equivalents.

What is claimed is:

1. A display device, comprising:
a first electrode layer;
a bank layer exposing the first electrode layer;
an element layer positioned on the first electrode layer and the bank layer and configured to emit at least three colors; and
a second electrode layer positioned on the element layer,
wherein the element layer includes:
a first hole injection layer positioned on the first electrode layer; and
a second hole injection layer positioned on the bank layer and having a different thickness from the first hole injection layer.

2. A display device, comprising:
a first electrode layer;
a bank layer exposing the first electrode layer;
an element layer positioned on the first electrode layer and the bank layer and configured to emit at least three colors; and
a second electrode layer positioned on the element layer,
wherein the element layer includes:
a first hole injection layer positioned on the first electrode layer; and
a second hole injection layer positioned on the bank layer and having a different resistance value from the first hole injection layer.

3. The display device of claim 1, wherein, in the element layer, the second hole injection layer positioned on the bank layer is thicker than the first hole injection layer positioned on the first electrode layer.

4. The display device of claim 2, wherein, in the element layer, the resistance value of the second hole injection layer positioned on the bank layer is lower than a resistance value of the first hole injection layer positioned on the first electrode layer.

5. The display device of claim 1, wherein the element layer is configured to emit white light based on layers laminated in an order of a red element layer, a blue element layer, and a green element layer.

6. The display device of claim 2, wherein the element layer is configured to emit white light based on layers laminated in an order of a red element layer, a blue element layer, and a green element layer.

7. The display device of claim 1, wherein the element layer is configured to emit white light based on layers laminated in an order of a red element layer, a first blue element layer, a green element layer, and a second blue element layer.

8. The display device of claim 2, wherein the element layer is configured to emit white light based on layers laminated in an order of a red element layer, a first blue element layer, a green element layer, and a second blue element layer.

9. The display device of claim 1, wherein the bank layer includes a recessed or protruding structure.

10. The display device of claim 2, wherein the bank layer includes a recessed or protruding structure.

11. A method of manufacturing a display device, comprising:
forming a first electrode layer;
forming a bank layer exposing the first electrode layer;
forming an element layer configured to emit at least three colors on the first electrode layer and the bank layer; and
forming a second electrode layer on the element layer,
wherein the forming of the element layer comprises:
forming a first hole injection layer on the first electrode layer and the bank layer using a first source; and
forming a second hole injection layer on the bank layer using a second source.

12. The method of claim 11, wherein the forming of the second hole injection layer includes using a mask exposing only the bank layer and blocking the remaining area.

13. The method of claim 11, wherein the first source and the second source are identical or different.
